(19) United States
(12) Patent Application Publication
(10) Pub. No.: US 2021/0065974 A1
(43) Pub. Date: Mar. 4, 2021

(54) COIL COMPONENT AND METHOD FOR MANUFACTURING SAME

(71) Applicant: TAIYO YUDEN CO., LTD., Tokyo (JP)

(72) Inventors: Yoko ORIMO, Takasaki-shi (JP); Tomoo KASHIWA, Takasaki-shi (JP); Takashi NAKAJIMA, Takasaki-shi (JP)

(21) Appl. No.: 17/002,703

(22) Filed: Aug. 25, 2020

(30) Foreign Application Priority Data
Aug. 30, 2019 (JP) 2019-158454

(51) Int. Cl. H01F 41/04; H01F 27/255; H01F 1/24; H01F 27/32

(52) U.S. Cl. CPC H01F 41/041; H01F 27/324; H01F 1/24; H01F 27/255

(57) ABSTRACT

A magnetic body of the coil component is constituted by soft magnetic metal grains joined together via a glass phase, wherein the soft magnetic metal grains contain Fe in their metal part and also have, on their surface, an amorphous insulation layer containing Si and O, and wherein the percentage by mass of Si relative to all elements in the insulation layer is higher than that in the glass phase. The coil component can offer improved dielectric breakdown voltage.

### CROSS-REFERENCE TO RELATED APPLICATIONS

The present application claims priority to Japanese Patent Application No. 2019-158454, filed Aug. 30, 2019, the disclosure of which is incorporated herein by reference in its entirety including any and all particular combinations of the features disclosed therein.

### BACKGROUND

### Field of the Invention

The present invention relates to a coil component and a method for manufacturing the same.

### Description of the Related Art

For coil components, inductance and other basic properties are determined by which magnetic body and conductor are combined. In particular, the properties of a coil component are significantly affected by the magnetic material that constitutes its magnetic body and, therefore, normally different coil components use different magnetic materials according to their construction, use environment, etc. For example, ferrite-type magnetic materials offering excellent dielectric strength are often adopted by coil components for automobiles that are required to operate at high voltage.

In recent years, however, metal magnetic materials are beginning to replace ferrite types for use in coil components for automobiles. This is because metal magnetic materials, which are less likely to saturate magnetically compared to ferrite-type materials, allow for size reduction of coil components. The number of electronic components used on automobiles is increasing in recent years due to their computerization. In the meantime, the space available for installing electronic components and boards carrying electronic components is limited, which is imposing a requirement that the electronic components be made smaller. It is in response to this requirement that coil components featuring metal magnetic materials are beginning to be adopted.

Metal magnetic materials, while more advantageous to ferrite types in that they are less likely to saturate magnetically, are inferior to ferrite types in terms of electrical insulating property. For this reason, magnetic bodies made of metal magnetic materials may conduct electricity under high voltage. Magnetic bodies made of metal magnetic materials are constituted by metal magnetic grains that are in contact with one another. Accordingly, various means have been studied for improving the electrical insulating property of these magnetic bodies, with the focus on electrically insulating the surfaces of metal magnetic grains. As examples, the following have been reported.

[1] Grains of a metal magnetic material containing Fe are coated with a mixture of titanium alkoxide and silicon alkoxide and pressure-formed into a powder made of the grains, which is then heat-treated in an 850° C. argon atmosphere to obtain a powder magnetic core (Patent Literature 1).

[2] Fe—Si alloy grains are oxidized in a weak oxidizing atmosphere of water vapor, etc., to form an SiO₂ oxide film on the grain surface, after which the grains are formed and then sintered in a weak oxidizing atmosphere of water vapor, etc., at the final attained temperature in a range of 600 to 1100° C., to obtain a core material (Patent Literature 2).

[3] A powder of a soft magnetic alloy containing Fe is formed and then heat-treated at a temperature of 400 to 900° C. in air or other oxygen-containing atmosphere, to form an insulation layer made of an oxide on the surface of each grain constituting the powder, and thereby obtain a core (Patent Literature 3).

### BACKGROUND ART LITERATURES

[Patent Literature 1] Japanese Patent Laid-open No. 2018-182040

[Patent Literature 2] Japanese Patent Laid-open No. 2006-49625

[Patent Literature 3] Japanese Patent Laid-open No. 2011-249774

### SUMMARY

It had been considered that, according to the aforementioned means under [1] to [3], an insulation layer of reduced thickness is formed on the surfaces of metal magnetic grains containing Fe, and therefore the electrical insulating property can be improved while inhibiting magnetic permeability and other magnetic properties from dropping. However, an investigation by the inventor of the present invention revealed that cores or coil components obtained by the aforementioned means could include those subject to dielectric breakdown at relatively low voltages.

Accordingly, an object of the present invention is to provide a coil component offering improved dielectric breakdown voltage.

During the course of studying to achieve the aforementioned object, the inventors of the present invention came to a hypothesis that, as shown in Patent Literature 3 (Paragraph [0047], FIG. 3(b)), the Fe content in the insulation layer could be causing the dielectric breakdown voltage to drop. Specifically, according to the aforementioned means under [1] to [3], strength of the core is achieved by joining the metal magnetic grains together via an insulation layer made of an oxide, and therefore heat treatment at a relatively high temperature or for a relatively long period, or heat treatment in a strong oxidizing atmosphere, is performed. Such heat treatment causes the Fe in the metal magnetic grains to diffuse and enter the insulation layer and then pass through the layer. Changes to the atomic arrangements in the insulation layer occurring at the time of this entry or pass-through by Fe affect the breakdown of electrical insulating property under application of high voltage.

Accordingly, the inventors of the present invention studied further, based on the aforementioned hypothesis, with the aim of inhibiting the entry of Fe into the insulation layer. As a result, the inventors of the present invention found that the dielectric strength voltage can be improved by bonding soft magnetic grains together via a glass phase and thereby eliminating the need for heat treatment at a high temperature, for a long period, or in a strong oxidizing atmosphere, and eventually completed the present invention.

To be specific, a first aspect of the present invention to achieve the aforementioned object is a coil component comprising: a magnetic body containing soft magnetic metal grains; and a conductor placed inside or on the surface of the magnetic body; wherein such coil component is characterized in that: in the magnetic body, the soft magnetic metal grains are joined together via a glass phase; each soft magnetic metal grain contains Fe in its metal part under its surface and has, on the surface, an amorphous insulation layer, other than the glass phase, containing Si and O and covering the metal part; and the percentage by mass of Si relative to all elements in the insulation layer is higher than a percentage by mass of Si relative to all elements in the glass phase.

Additionally, a second aspect of the present invention is a method for manufacturing a coil component comprising: a magnetic body containing soft magnetic metal grains; and a conductor placed inside or on the surface of the magnetic body; wherein such method for manufacturing a coil component includes: (a1) preparing a soft magnetic metal powder containing Fe; (b1) depositing an Si-containing substance onto the surface of each grain constituting the soft magnetic metal powder; (d1) mixing the soft magnetic metal powder obtained in (b1) above, with a glass powder, to obtain a mixed powder; (e1) forming the mixed powder obtained in (d1) above, to obtain a compact; (f1) heat-treating the compact obtained in (e1) above, in an atmosphere of 800 ppm or lower in oxygen concentration at a temperature of 500 to 1000° C., to obtain a magnetic body; and (g1) performing at least one of (1) and (2) below: (1) placing a conductor or precursor thereto inside or on the surface of the compact in (e1) above; and (2) placing a conductor inside or on the surface of the magnetic body after performing (f1) above.

Additionally, a third aspect of the present invention is a method for manufacturing a coil component comprising: a magnetic body containing soft magnetic metal grains; and a conductor placed inside or on the surface of the magnetic body; wherein such method for manufacturing a coil component includes: (a2) preparing a soft magnetic metal powder containing Fe, Si, and at least one of Cr and Mn; (d1) mixing the soft magnetic metal powder with a glass powder, to obtain a mixed powder; (e1) forming the mixed powder obtained in (d1) above, to obtain a compact; (f2) heat-treating the compact obtained in (e1) above, in an atmosphere of 10 to 800 ppm or less in oxygen concentration at a temperature of 500 to 900° C., to obtain a magnetic body; and (g1) performing at least one of (1) and (2) below: (1) placing a conductor or precursor thereto inside or on the surface of the compact in (e1) above; and (2) placing a conductor on the surface of the magnetic body after performing (f2) above.

Additionally, a fourth aspect of the present invention is a circuit board carrying the aforementioned coil component.

According to the present invention, a coil component offering improved dielectric breakdown voltage can be provided.

### BRIEF DESCRIPTION OF THE DRAWINGS

FIG. 1 is a drawing explaining the microstructure of the magnetic body in the coil component pertaining to an aspect of the present invention.

FIG. 2 shows schematic drawings explaining steps (1) to (4) to confirm that the insulation layer is amorphous in the present invention (a non-amorphous structure is conformed in the left drawings whereas an amorphous structure is confirmed in the right drawings).

FIG. 3 is a schematic drawing showing an exterior view of the coil component produced in each Example or Comparative Example of the present invention.

FIG. 4 is a schematic drawing showing how a test piece was supported and a load was applied thereto in the 3-point bending test conducted in the Examples and Comparative Examples of the present invention.

### DESCRIPTION OF THE SYMBOLS

| | |
|---|---|
| 1 | Coil component |
| 2 | Magnetic body |
| 21 | Soft magnetic metal grain |
| 211 | Metal part |
| 212 | Insulation layer |
| 22 | Glass phase |
| 3 | External electrode |

### DETAILED DESCRIPTION OF ASPECTS

The constitutions as well as operations and effects of the present invention are explained below, together with the technical ideas, by referring to the drawings. It should be noted, however, that the mechanisms of operations include estimations and whether they are correct or wrong does not limit the present invention in any way. Also, of the components in the aspects below, those components not described in the independent claims representing the most generic concepts are explained as optional components. It should be noted that a description of numerical range (description of two values connected by “to”) is interpreted to include the described values as the lower limit and the upper limit.

[Coil Component]

The coil component pertaining to the first aspect of the present invention (hereinafter also referred to simply as “first aspect”) comprises a magnetic body containing soft magnetic grains, as well as a conductor placed inside or on the surface of the magnetic body. In the magnetic body, the soft magnetic metal grains are joined together via a glass phase. Also, the soft magnetic metal grains contain Fe and also have, on their surface, an amorphous insulation layer containing Si and O. In addition, the percentage by mass of Si relative to all elements in the insulation layer is higher than that in the glass phase.

The magnetic body and conductor in the first aspect are described in detail below. In some embodiments, any one or more elements described as alternative or optional element(s) in the present disclosure can explicitly be eliminated from the soft magnetic grains. Further, in some embodiments, the material/composition may consist of required/explicitly indicated elements described in the present disclosure; however, “consisting of” does not exclude additional components that are unrelated to the invention such as impurities ordinarily associated therewith.

<About Magnetic Body>

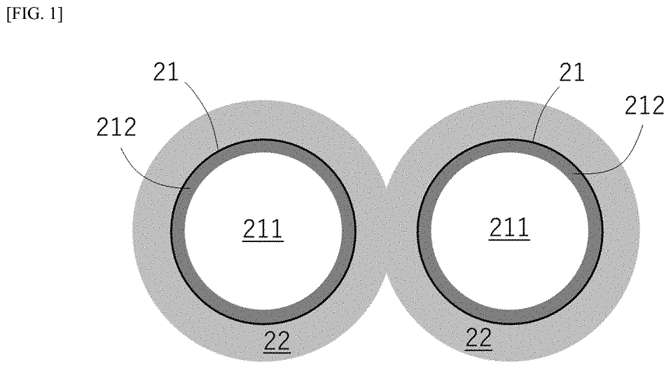

The magnetic body in the first aspect is constituted, as shown in FIG. 1, by soft magnetic metal grains 21 that are joined together via a glass phase 22.

The soft magnetic metal grains 21 have Fe as an essential component. The magnetic permeability of the magnetic body or coil component improves as the Fe content in the soft magnetic metal grains 21 increases. Accordingly, preferably the Fe content is increased as much as possible to the extent that the desired dielectric strength can be achieved. A preferred content of Fe is 30 percent by mass or higher, while its content is more preferably 50 percent by mass or higher, or yet more preferably 70 percent by mass or higher. When the content of Fe becomes too high, on the other hand, diminished properties due to oxidation of Fe will become of concern. Accordingly, preferably the content of Fe is kept to 98 percent by mass or lower.

The soft magnetic metal grains 21 may contain elements other than Fe. When Si is contained, for example, the grains have higher electrical resistance and their magnetic characteristics can be inhibited from dropping due to eddy current. Also, when the grains contain Cr, Mn, or other non-Si element that oxidizes more easily than Fe (hereinafter also referred to as “M” or “element M”), their magnetic properties can be stabilized as oxidation of Fe is inhibited.

The soft magnetic metal grains 21 may all have a given composition or grain size, or they may be a mixture of grains having different compositions or grain sizes. When multiple types of metal grains having different compositions or grain sizes are present at appropriate percentages, optimization of magnetic properties, electrical insulating property, and mechanical strength of the magnetic body becomes possible.

The soft magnetic metal grains 21 each comprise, as shown in FIG. 1, an insulation layer 212 formed on the surface and a metal part 211 positioned on the interior side of the insulation layer 212.

The insulation layer 212 contains Si and O as constituent elements, and is amorphous. This allows it to exhibit high insulating resistance with a reduced thickness, and also achieve high dielectric breakdown voltage. So long as it remains in an amorphous state, the insulation layer 212 may contain elements other than Si and O, and its type and content are not limited in any way. However, preferably Fe is contained by as little as possible because Fe, at a relatively low concentration, causes the insulation layer to crystallize, leading to a significant drop in the dielectric breakdown voltage of the magnetic body and the coil component.

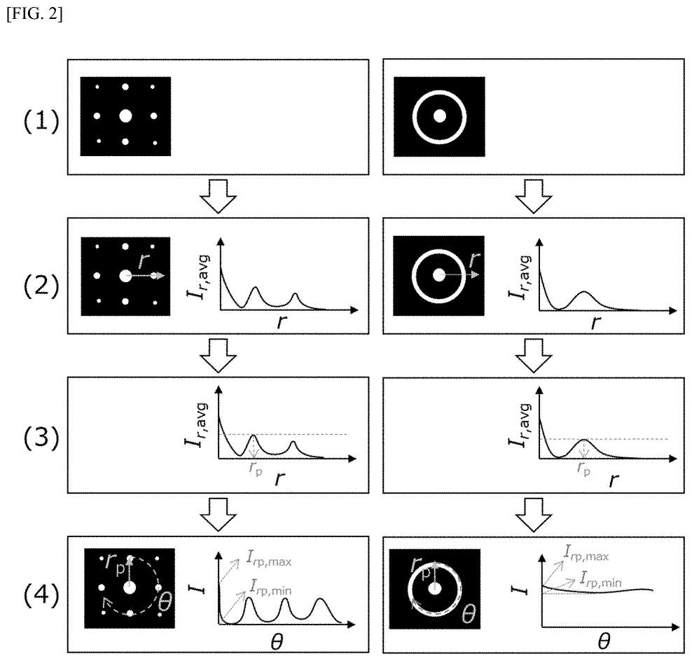

Now, amorphousness of the insulation layer 212 is confirmed by the following steps. FIG. 2 shows schematic drawings explaining steps (1) to (4) to confirm that the insulation layer is amorphous in the present invention (a non-amorphous structure is conformed in the left drawings whereas an amorphous structure is confirmed in the right drawings). First, a thin sample that has been cut out from the magnetic body is observed with a high-resolution transmission electron microscope (HR-TEM), and a reciprocal space image of the insulation layer, as recognized by contrast (brightness) differences on the electron microgram, is obtained by Fourier transform (refer to FIG. 2 (1)). It should be noted that, this reciprocal space image may be obtained using any measuring device other than HR-TEM, so long as it uses nano-beam diffraction. Next, on the obtained reciprocal space image, the average value of signal strength I_{r, avg} is calculated for each distance r from the position of incidence of the beam. To be specific, the signal strength Iᵣ is measured at multiple points located at an equal distance r from the position of incidence of the beam, and the results are averaged. Next, the radial distribution function is obtained based on the obtained I_{r, avg} and r (refer to FIG. 2 (2)). Next, using the radial distribution function, the point rₚ at which the signal strength becomes the maximum, other than the point where r=0, is obtained (refer to FIG. 2 (3)). Lastly, the signal strengths at the points of distance rₚ from the position of incidence of the beam are plotted against the angle of rotation θ, and the maximum signal strength Iᵣₚ, max and the minimum signal strength I_{rp, min}, among the signal strengths at the respective points, are compared (refer to FIG. 2 (4)). Then, when the value of I_{rp, max} is less than 1.5 times the value of I_{rp, min}, the observed insulation layer is determined as amorphous.

When the maximum value of Si content in the insulation layer 212 is compared with that in the glass phase 22 described below, the insulation layer 212 contains more Si than does the glass phase 22. This allows for increase in electrical insulating property among the soft magnetic metal grains 21.

As described above, when the soft magnetic metal grains 21 contain elements other than Fe, preferably the non-Fe elements contained in the metal part 211 and those in the insulation layer 212 are the same. When the metal part 211 and the insulation layer 212 contain the same types of elements, adhesion between the two improves and this allows for stabilization of electrical insulating property and improvement of mechanical strength. Such soft magnetic metal grains 21 can be obtained by heat-treating a soft magnetic metal powder used as the material, or a compact containing such powder, in a weak oxidizing atmosphere.

Now, the compositions of the metal part 211 and insulation layer 212 of the soft magnetic metal grain 21, and composition of the glass phase 22, are confirmed by the following steps.

First, a randomly selected thin sample of 50 to 100 nm in thickness is taken from the center part of the coil component using a focused ion beam (FIB) device, and immediately thereafter the magnetic body part is observed using a scanning transmission electron microscope (STEM) carrying an annular dark-field detector as well as an energy-dispersive X-ray spectroscopy (EDS) detector. Next, the metal part, insulation layer, and glass phase are identified from the contrast (brightness) differences on the electron microgram, and the composition (weight concentration or percentage by mass) of each part in a randomly selected 200×200 nm region is calculated by the EDS according to the ZAF method. The STEM-EDS measurement conditions are set to 200 kV for acceleration voltage and 1.0 nm for electron beam diameter, and the measurement period is set so that the integral value of signal strengths in a range of 6.22 to 6.58 keV at the respective points in the soft magnetic metal grain part becomes a 25 count or higher.

It should be noted that, if the compositions of the soft magnetic metal powder and glass powder used in the manufacture of the magnetic body are known, the known compositions may be used as the compositions of the metal part 211 and glass phase, respectively.

The glass phase 22 joins the soft magnetic metal grains 21 together and thus contributes to the shape retention and strength improvement of the magnetic body in which they are contained, and also improves electrical insulating property among the grains 21. The type of glass that constitutes the glass phase 22 is not limited in any way. Examples include borosilicate-based glass, phosphate-based glass, bismuthate-based glass, and the like.

Preferably the glass phase 22 contains Si in that it improves its adhesion with the soft magnetic metal grain 21. This is because Si in the insulation layer 212 present on the surface of the soft magnetic metal grain 21 forms a molecular bond with Si in the glass phase. Also, the glass phase may contain Al, Zr, Ti, or other element for higher corrosion resistance.

The magnetic body in the first aspect may contain various fillers, etc., other than the aforementioned soft magnetic metal grains and glass phase, to the extent that desired properties can be achieved.

<About Conductor>

The material, shape, and layout of the conductor are not limited in any way, and may be determined as deemed appropriate according to the required properties. Examples of the material include silver or copper, or alloys thereof, for example. Also, examples of the shape include straight, meandering, planar coil, spiral, etc. Furthermore, examples of the layout include winding of a sheathed conductive wire around the magnetic body, embedding of conductors of various shapes into the magnetic body, and the like.

[Method for Manufacturing Coil Component 1]

The method for manufacturing a coil component pertaining to the second aspect of the present invention (hereinafter also referred to simply as “second aspect”) includes the following processing operations:

(a1) preparing a soft magnetic metal powder containing Fe;

(b1) depositing an Si-containing substance onto the surface of each grain constituting the soft magnetic metal powder;

(d1) mixing the soft magnetic metal powder obtained in (b1) above, with a glass powder, to obtain a mixed powder;

(e1) forming the mixed powder obtained in (d1) above, to obtain a compact;

(f1) heat-treating the compact obtained in (e1) above, in an atmosphere of 800 ppm or lower in oxygen concentration at a temperature of 500 to 1000° C., to obtain a magnetic body; and

(g1) performing at least one of (1) placing a conductor or precursor thereto inside or on the surface of the compact in (e1) above, and (2) placing a conductor on the surface of the magnetic body after performing (f1) above.

The above processing operations are described in detail below. It should be noted that, in the second aspect, it goes without saying that any processing operations known to those skilled in the art, other than the above processing operations, may also be performed.

<About Processing Operation (a1)>

The soft magnetic metal powder used in the second aspect contains Fe as an essential component. As described above, the magnetic permeability of the magnetic body or coil component improves as the Fe content in the soft magnetic metal grains constituting it increases. This means that, for the soft magnetic metal powder being used as the material, preferably one with a higher Fe content is used. A preferred content of Fe is 30 percent by mass or higher, while its content is more preferably 50 percent by mass or higher, or yet more preferably 70 percent by mass or higher. When the content of Fe becomes too high, on the other hand, diminished properties of the magnetic body or coil component due to oxidation of Fe will become of concern. Accordingly, preferably the content of Fe is kept to 98 percent by mass or lower.

The soft magnetic metal powder may contain elements other than Fe as components. When Si is contained, for example, the electrical insulating property of the insulating film formed by the heat treatment described below can be improved. Also, when a non-Si element that oxidizes more easily than Fe (element M) is contained, entry of Fe into the insulating film during the heat treatment described below, and consequent crystallization of the insulating film, can be inhibited. Examples of element M include Cr, Mn, Al, Zr, Ti, Ni, etc. Among these, Cr or Mn is preferred in that crystallization of the insulating film can be inhibited more effectively.

The grain size of the soft magnetic metal powder is not limited in any way, and the average grain size (median diameter (D₅₀)) calculated from the granularity distribution measured on volume basis may be 0.5 to 30 μm, for example. Preferably the average grain size is set to 1 to 10 μm. This average grain size can be measured using a granularity distribution measuring device utilizing the laser diffraction/scattering method.

<About Processing Operation (b1)>

In Processing Operation (b1), an Si-containing substance is deposited onto the surface of each grain constituting the soft magnetic metal powder.

Examples of the Si-containing substance to be used include tetraethoxysilane (TEOS) and other silane coupling agents, as well as colloidal silica and other fine silica grains, and the like. The use quantity of the Si-containing substance may be determined as deemed appropriate according to the type of the substance, grain size of the soft magnetic metal grain, etc.

Examples of the method for depositing an Si-containing substance onto the surface of the soft magnetic metal grains include, when the substance is liquid, a method of spraying it onto the grains or immersing the grains in it, followed by drying. Also, when the Si-containing substance is particulate, examples include a dry mixing method and a method of allowing the grains to come in contact (by means of spraying or immersion) with a slurry in which the substance is dispersed, followed by drying. Furthermore, coating by the sol-gel method using a silane coupling agent may be adopted.

<About Processing Operation (c1)>

The second aspect may include heat-treating the soft magnetic metal powder, which has the Si-containing substance deposited onto its surface, in an inert gas atmosphere at a temperature of 100 to 700° C. or in an atmosphere of 100 ppm or lower in oxygen concentration at a temperature of 100 to 300° C. (Processing Operation (c1)), following Processing Operation (b1) above. Here, inert gas refers to N₂ or a noble gas. This way, the Si-containing substance deposited onto the surface of the metal grains constituting the soft magnetic metal powder forms a thin amorphous film containing Si and O, and the formed thin film exhibits improved mechanical strength and adhesion strength to the metal grains. This thin film functions as an insulation layer in the magnetic body inside the coil component to electrically insulate between the soft magnetic metal grains.

Preferably the heat treatment temperature is 100° C. or higher. This promotes the aforementioned formation of a thin amorphous film. Also, it improves the mechanical strength of the formed thin film and its adhesion strength to the metal grains. However, an excessively high heat treatment temperature leads to noticeable oxidation of the soft magnetic metal powder or crystallization of the thin amorphous film, causing properties of the obtained magnetic body to drop. For this reason, preferably the heat treatment temperature is set to 300° C. or lower when the heat treatment is performed in an atmosphere containing no more than 100 ppm of oxygen. When the heat treatment is performed in an inert atmosphere, on the other hand, the soft magnetic metal powder is hardly oxidized and therefore the upper limit of heat treatment temperature may be set to 700° C.

The holding period at the heat treatment temperature is not limited in any way, but from the viewpoints of sufficiently forming a thin amorphous film, and of sufficiently increasing the mechanical strength of the formed thin film and its adhesion strength to the metal grains, it is set preferably to 30 minutes or longer, or more preferably to 50 minutes or longer. Conversely, from the viewpoints of inhibiting a crystalline film from being produced, while completing the heat treatment quickly and thereby improving productivity, the heat treatment period is set preferably to 2 hours or shorter, or more preferably to 1.5 hours or shorter.

<About Processing Operation (c2)>

Also, the second aspect may include heat-treating the soft magnetic metal powder, which has the Si-containing substance deposited onto its surface, in an atmosphere of 3 to 100 ppm in oxygen concentration at a temperature of 300 to 900° C. (Processing Operation (c2)) in place of Processing Operation (c1) above, if the soft magnetic metal powder contains Si or element M. This causes Si or element M in the metal grains constituting the soft magnetic metal powder to diffuse to the surface of the grains and oxidize at the surface. At this time, a thin amorphous oxide film is formed on the surface of the metal grains, which means that, together with the thin amorphous film derived from the Si-containing substance, a thin amorphous film of sufficient thickness can be formed. This thin film functions as an insulation layer in the magnetic body inside the coil component to electrically insulate between the soft magnetic metal grains. As a result, a magnetic body or coil component can be obtained that offers excellent electrical insulating property and produces minimal driving loss.

Setting the oxygen concentration in the heat treatment atmosphere to 3 ppm or higher and the heat treatment temperature to 300° C. or higher promotes the reaction between Si and element M contained in the soft magnetic metal powder, and oxygen. And, this allows the surface of the soft magnetic metal grains constituting the soft magnetic metal powder to be coated with an amorphous film of high electrical insulating property. On the other hand, setting the oxygen concentration in the heat treatment atmosphere to 100 ppm or lower and the heat treatment temperature to 900° C. or lower inhibits excessive oxidation of Fe in the soft magnetic metal grains and consequent production of crystalline oxide at the grain surface. And, this prevents dropping of magnetic properties and electrical insulating property. Preferably the aforementioned oxygen concentration is set to 5 ppm or higher. Also, the aforementioned oxygen concentration is set preferably to 50 ppm or lower, or more preferably to 30 ppm or lower, or yet more preferably to 10 ppm or lower. On the other hand, the aforementioned heat treatment temperature is set preferably to 350° C. or higher, or more preferably to 400° C. or higher. Also, the aforementioned heat treatment temperature is set preferably to 850° C. or lower, or more preferably to 800° C. or lower.

The holding period at the heat treatment temperature is not limited in any way, but from the viewpoint of ensuring a sufficient thickness of the amorphous film, it is preferably set to 30 minutes or longer, or more preferably to 1 hour or longer. Conversely, from the viewpoints of inhibiting a crystalline film from being produced, while completing the heat treatment quickly and thereby improving productivity, the heat treatment period is set preferably to 5 hours or shorter, or more preferably to 3 hours or shorter.

Here, the aforementioned reaction between elements in the soft magnetic metal grains and oxygen (oxidation), and consequent production of crystalline oxide at the grain surface, can be inhibited by lowering at least one of the oxygen concentration in the heat treatment atmosphere and the heat treatment temperature, or by shortening the heat treatment period. This means that the heat treatment temperature should be lowered or the heat treatment period shortened, if, for example, maximum inhibition of oxidation of a given metal or alloy element is desired in a situation where the oxygen concentration in the heat treatment atmosphere must be raised. Additionally, if the heat treatment temperature must be raised, the oxygen concentration in the heat treatment atmosphere should be lowered or the heat treatment period shortened. Furthermore, if the heat treatment period must be extended, the oxygen concentration in the heat treatment atmosphere should be lowered or the heat treatment temperature lowered.

<About Processing Operation (d1)>

In Processing Operation (d1), the soft magnetic metal powder that has completed the processing operation in (b1) above, is mixed with a glass powder to obtain a mixed powder.

Examples of the type of glass powder to be used include borosilicate-based glass, phosphate-based glass, bismuthate-based glass, and the like. Use of a glass whose softening point is 1000° C. or lower improves flowability during the heat treatment in (f1) mentioned below, thereby allowing the soft magnetic metal grains to be joined together over a wider area. This, in turn, improves the joining strength between the magnetic soft metal grains, and a high-strength magnetic body is formed as a result. The glass softening point may be adjusted by adding any of various elements such as alkali metal elements, alkali earth metal elements, as well as Cr, Mn, Co, Zn, Cu, and the like. Also, the glass powder may contain Al, Zr, Ti, or other element to enhance the corrosion resistance of the magnetic body. While the grain size of the glass powder used is not limited in any way, a glass powder of a smaller grain size than the soft magnetic metal grains is preferred from the viewpoint of facilitating the glass powder grains to be placed between the soft magnetic metal grains in the mixed powder.

Regarding the method for mixing the soft magnetic metal powder and the glass powder, any method commonly used for powder mixing may be adopted. Examples include using a ribbon blender, V-type mixer, or any of various other types of mixers, as well as mixing using a ball mill, and the like.

<About Processing Operation (e1)>

In Processing Operation (e1), the mixed powder obtained in (d1) above is formed to obtain a compact.

The forming method is not limited in any way and, for example, it may be one whereby the soft magnetic metal powder is mixed with a resin and the mixture is supplied to dies or other molds, which are then pressed using a press, etc., followed by curing of the resin. Also, a method of stacking and pressure-bonding green sheets that contain the soft magnetic metal powder may also be adopted.

When a compact is obtained by means of press-forming using dies, etc., the press conditions may be determined as deemed appropriate according to the type of soft magnetic metal powder, type of resin to be mixed therewith, and compounding ratios of the two, for example.

The resin to be mixed with the soft magnetic metal powder is not limited in any way so long as it can bond the grains of the soft magnetic metal powder together and form and keep them in shape, and also volatilizes during the heat treatment in (f1) mentioned below without leaving residues of carbon content, etc., behind. Examples include acrylic resins, butyral resins, vinyl resins, etc., whose decomposition temperatures are 500° C. or lower. Also, a lubricant, representative examples of which include stearic acid and salts thereof, phosphoric acid and salts thereof, as well as boric acids and salt thereof, may be used together with, or in place of, the resin. The additive quantity of the resin or lubricant may be determined as deemed appropriate by considering the formability, shape retainability, etc., such as 0.1 to 5 parts by mass relative to 100 parts by mass of the soft magnetic metal powder, for example.

When a compact is obtained by stacking and pressure-bonding green sheets, a method of stacking individual green sheets using a suction transfer machine, etc., and then pressure-bonding them using a press machine, may be adopted. If multiple coil components are to be obtained from the pressure-bonded laminated body, the laminated body may be divided using a dicing machine, laser cutting machine, or other cutting machine.

In this case, the green sheets are typically manufactured by applying a slurry containing the soft magnetic metal powder and a binder on the surface of plastic films or other base films using a doctor blade, die coater, or other coating machine, followed by drying. The binder to be used is not limited in any way so long as it can form the soft magnetic metal powder into a sheet shape and retain this shape, while allowing its carbon content, etc., to be removed by heat treatment without leaving any residues behind. Examples include polyvinyl butyral and other polyvinyl acetal resins, etc. The solvent with which to prepare the aforementioned slurry is not limited in any way, either, and butyl carbitol or other glycol ether, etc., may be used. The content of each component in the slurry may be adjusted as deemed appropriate according to the adopted method for forming the green sheets, thickness of the green sheets to be prepared, and so on.

<About Processing Operation (f1)>

In Processing Operation (f1), the compact obtained in (e1) above is heat-treated in an atmosphere of 800 ppm or lower in oxygen concentration at a temperature of 500 to 1000° C., to obtain a magnetic body. This volatilizes and removes the resin (binder) in the compact, while softening or fluidizing the glass powder in the compact and joining the soft magnetic metal grains together. The heat treatment to volatilize and remove the resin (binder) in the compact may be performed separately prior to Processing Operation (f1). In this case, preferably the heat treatment atmosphere is set to 10 ppm or higher in oxygen concentration, while the heat treatment temperature is set to 400° C. or lower to inhibit Fe from oxidizing.

The oxygen concentration in the heat treatment atmosphere is set to 800 ppm or lower. This inhibits Fe in the soft magnetic metal grains from oxidizing and entering the amorphous film, and the amorphous film from crystallizing as a result. The aforementioned oxygen concentration is set preferably to 500 ppm or lower, or more preferably to 300 ppm or lower. So long as an amorphous film has been formed sufficiently in Processing Operation (b1) above, or in Processing Operation (c1) or (c2) that may be performed in addition thereto, the oxygen concentration in the heat treatment atmosphere may be set to 0 ppm, or specifically the heat treatment atmosphere may contain virtually no oxygen. In this case, an inert gas should be used as the atmosphere gas. If, on the other hand, the amorphous film has not been formed sufficiently, its formation may be promoted by adding oxygen slightly to the heat treatment atmosphere.

The heat treatment temperature is set to 500 to 1000° C. Setting the heat treatment temperature to 500° C. or higher softens or fluidizes the glass powder in the compact to wet the surface of the soft magnetic metal grains coming in contact therewith, so that the soft magnetic metal grains can be joined together. On the other hand, setting the heat treatment temperature to 1000° C. or lower inhibits Fe in the soft magnetic metal grains from oxidizing and entering the amorphous film, and the amorphous film from crystallizing as a result. The aforementioned heat treatment temperature is set preferably to 550° C. or higher, or more preferably to 600° C. or higher. Also, the heat treatment temperature is set preferably to 950° C. or lower, or more preferably to 900° C. or lower.

The heat treatment period only needs to be such that the glass powder in the compact softens or fluidizes and extends in between the soft magnetic metal grains, and that an amorphous film of sufficient thickness is formed on the surface of the soft magnetic metal grains. As examples, it is set preferably to 30 minutes or longer, or more preferably to 1 hour or longer, from the viewpoint of obtaining such microstructure. Conversely, from the viewpoint of completing the heat treatment quickly and thereby improving the productivity, the heat treatment period is set preferably to 5 hours or shorter, or more preferably to 3 hours or shorter.

Now, the aforementioned oxidation of Fe and its entry into the amorphous film during the heat treatment can be inhibited by lowering at least one of the oxygen concentration in the heat treatment atmosphere and the heat treatment temperature, or by shortening the heat treatment period. This means that the heat treatment temperature should be set lower or the heat treatment period shortened, if, for example, maximum inhibition of oxidation of a given metal element is desired in a situation where the oxygen concentration in the heat treatment atmosphere must be raised. Additionally, if the heat treatment temperature must be raised, the oxygen concentration in the heat treatment atmosphere should be lowered or the heat treatment period shortened. Furthermore, if the heat treatment period must be extended, the oxygen concentration in the heat treatment atmosphere should be lowered or the heat treatment temperature lowered.

<About Processing Operation (g1)>

In Processing Operation (g1), a conductor or precursor thereto is placed. Here, a conductor is something that serves directly as a conductor in the coil component, while a precursor to a conductor is something that contains a binder resin, etc., in addition to a conductive material that will become a conductor in the coil component, and becomes a conductor when heat-treated. Regarding how a conductor or precursor thereto is placed, the following two methods are available.

(1) Place a Conductor or Precursor thereto Inside or on the Surface of the Compact in Processing Operation (e1) Above

When the compact is obtained by the aforementioned press forming, a method of filling the soft magnetic metal powder in dies where a conductor or precursor thereto has been placed beforehand, and then pressing the dies, can be adopted. This way, the conductor or precursor thereto can be placed inside the compact.

Or, when the compact is obtained by the aforementioned stacking and pressure-bonding of green sheets, a method of placing a precursor to a conductor on green sheets by printing a conductor paste, etc., and then stacking and pressure-bonding the green sheets, can be adopted. This way, the conductor or precursor thereto can be placed inside or on the surface of the laminated body.

The conductor paste to be used may be one containing a conductor powder and an organic vehicle. For the conductor powder, a powder of silver or copper, or alloys thereof, etc., is used. The grain size of the conductor powder is not limited in any way, but a conductor powder whose average grain size (median diameter (D₅₀)) calculated from the granularity distribution measured on volume basis is 1 to 10 μm, may be used, for example. The composition of the organic vehicle may be determined by considering its compatibility with the binder contained in the green sheets. Examples include butyl carbitol and other glycol ether solvents in which polyvinyl butyral (PVB) or other polyvinyl acetal resin is dissolved or swelled. The compounding ratios of the conductor powder and organic vehicle in the conductor paste may be adjusted as deemed appropriate according to a paste viscosity appropriate for the printing machine to be used, film thickness of the conductor patterns to be formed, and the like.

In any of the aforementioned cases, the placed precursor to conductor will form a conductor in Processing Operation (f1) that follows.

(2) Place a Conductor on the Surface of the Magnetic Body After Performing Processing Operation (f1) Above

In this case, a conductor may be placed according to a method of winding a sheathed conductive wire around the obtained magnetic body, or a method of placing a precursor to conductor on the surface of the magnetic body by printing a conductor paste, etc., and then baking the paste using a sintering furnace or other heating device.

[Method for Manufacturing Coil Component 2]

The method for manufacturing a coil component pertaining to the third aspect of the present invention (hereinafter also referred to simply as “third aspect”) includes the following processing operations:

(a2) preparing a soft magnetic metal powder containing Fe, Si, and a non-Si element that oxidizes more easily than Fe;

(d2) mixing the soft magnetic metal powder with a glass powder, to obtain a mixed powder;

(e2) forming the mixed powder obtained in (d2) above, to obtain a compact;

(f2) heat-treating the compact obtained in (e2) above, in an atmosphere of 10 to 800 ppm in oxygen concentration at a temperature of 500 to 900° C., to obtain a magnetic body; and

(g2) performing at least one of (1) placing a conductor or precursor thereto inside or on the surface of the compact in (e2) above, and (2) placing a conductor on the surface of the magnetic body after performing (f2) above.

The above processing operations are described in detail below. However, processing operations that are also common to the aforementioned second aspect are not explained. It should be noted that, in the third aspect, it goes without saying that any processing operations known to those skilled in the art, other than the above processing operations, may also be performed.

<About Processing Operation (a2)>

The soft magnetic metal powder used in the third aspect contains Fe, Si, and a non-Si element that oxidizes more easily than Fe (element M). Use of a soft magnetic metal powder containing Si as the material causes the Si to diffuse to, and oxidize at, the surface of the metal grains constituting the soft magnetic metal powder during the heat treatment in (f2) or (c2) described below, and allows for formation of a thin amorphous film offering high electrical insulating property. Also, use of a soft magnetic metal powder containing element M as the material, means that the thin amorphous film formed by the heat treatment in (f2) or (c2) described below will contain such element, and oxidation of Fe in the metal part can be inhibited. As a result, a magnetic body or coil component offering high magnetic permeability can be obtained. The percentages of Si and element M in the soft magnetic metal powder are not limited in any way. One example is that Si is contained by 1 to 10 percent by mass, element M is contained by 0.5 to 5 percent by mass in total, and the remainder is accounted for by Fe and unavoidable impurities.

The grain size of the soft magnetic metal powder is not limited in any way, just as explained in <About Processing Operation (a1)> above. In an example, the average grain size (median diameter (D₅₀)) calculated from the granularity distribution measured on volume basis may be set to 0.5 to 30 μm. Preferably the average grain size is set to 1 to 10 μm.

<About Processing Operation (f2)>

In Processing Operation (f2), the compact obtained in (e1) above is heat-treated in an atmosphere of 10 to 800 ppm in oxygen concentration at a temperature of 500 to 900° C., to obtain a magnetic body. This heat treatment volatilizes and removes the resin (binder) in the compact. It also forms an amorphous film containing Si and element M on the surface of the soft magnetic metal grains, while softening or fluidizing the glass powder in the compact and joining the soft magnetic metal grains together. According to Processing Operation (f2), there is no need to process the soft magnetic metal powder per Processing Operation (b1) described above, whether alone or in combination with Processing Operation (c1) or (c2), which allows for simplification of the manufacturing steps. It should be noted that, as is the case with Processing Operation (f1) described above, the heat treatment to volatilize and remove the resin (binder) in the compact may be performed separately from Processing Operation (f2).

The oxygen concentration in the heat treatment atmosphere is set to 10 to 800 ppm. Setting the oxygen concentration in the heat treatment atmosphere to 10 ppm or higher promotes oxidation of Si and element M in the soft magnetic metal grains, allowing for formation of an amorphous film that contains these elements and 0 and offers high electrical insulating property. On the other hand, setting the oxygen concentration in the heat treatment atmosphere to 800 ppm or lower inhibits excessive oxidation of Fe in the soft magnetic metal grains, which in turn inhibits the magnetic properties from dropping. The aforementioned oxygen concentration is set preferably to 100 ppm or higher, or more preferably to 200 ppm or higher.

The heat treatment temperature is set to 500 to 900° C. Setting the heat treatment temperature to 500° C. or higher promotes oxidation of Si and element M in the soft magnetic metal grains, as well as their diffusion to the grain surface, allowing for formation of an amorphous film that contains these elements and O and offers high electrical insulating property. Also, it softens or fluidizes the glass powder in the compact to wet the surface of the soft magnetic metal grains coming in contact therewith, so that the soft magnetic metal grains can be joined together. On the other hand, setting the heat treatment temperature to 900° C. or lower inhibits Fe in the soft magnetic metal grains from oxidizing and diffusing to the grain surface, while also inhibiting a crystalline film from being produced on the grain surface as a result. The aforementioned heat treatment temperature is set preferably to 550° C. or higher, or more preferably to 600° C. or higher. Also, the heat treatment temperature is set preferably to 850° C. or lower, or more preferably to 800° C. or lower.

The heat treatment period only needs to be such that the glass powder in the compact softens or fluidizes and extends in between the soft magnetic metal grains, and that an amorphous film of sufficient thickness is formed on the surface of the soft magnetic metal grains. As examples, it is set preferably to 30 minutes or longer, or more preferably to 1 hour or longer, from the viewpoint of obtaining such microstructure. Conversely, from the viewpoint of completing the heat treatment quickly and thereby improving the productivity, the heat treatment period is set preferably to 5 hours or shorter, or more preferably to 3 hours or shorter.

Now, the aforementioned oxidation of Fe and its diffusion to the grain surface, and production of a crystalline film on the grain surface as a result, can be inhibited by lowering at least one of the oxygen concentration in the heat treatment atmosphere and the heat treatment temperature, or by shortening the heat treatment period. This means that the heat treatment temperature should be lowered or the heat treatment period shortened, if, for example, maximum inhibition of crystalline film production is desired in a situation where the oxygen concentration in the heat treatment atmosphere must be raised. Additionally, if the heat treatment temperature must be raised, the oxygen concentration in the heat treatment atmosphere should be lowered or the heat treatment period shortened. Furthermore, if the heat treatment period must be extended, the oxygen concentration in the heat treatment atmosphere should be lowered or the heat treatment temperature lowered.

<About Processing Operation (c3)>

In the third aspect, the soft magnetic metal powder may additionally be heat-treated in an atmosphere of 3 to 100 ppm in oxygen concentration at a temperature of 300 to 900° C. (Processing Operation (c3)) prior to (d1) above. This allows a thin amorphous film containing Si, O and element M to be formed at substantially uniform thickness (e.g., including manufacturing and/or measurement tolerance) on a predominant or substantially entire surface of the metal grains constituting the soft magnetic metal powder. This thin film functions as an insulation layer in the magnetic body inside the coil component to electrically insulate between the soft magnetic metal grains. As a result, a magnetic body or coil component having an insulation layer of consistent thickness, and offering excellent magnetic properties, can be obtained. It should be noted that, when Processing Operation (c3) is performed, Processing Operation (f3) which applies the same heat treatment atmosphere, temperature, and period as those in Processing Operation (f1) described above may be adopted in place of Processing Operation (f2) above. This is because Processing Operation (f2) is performed not only with the intent of joining the soft magnetic metal grains together by softening the glass powder, but also with the intent of forming a thin amorphous film that serves as an insulation layer. Adopting Processing Operation (f3) has an advantage in that the heat treatment can be performed in an atmosphere that contains virtually no oxygen.

The reasons for setting the heat treatment atmosphere, temperature, and period in Processing Operation (c2) as described above are the same as those applicable to Processing Operation (c2) performed optionally in the aforementioned second aspect, and therefore not explained.

According to the second aspect and third aspect explained above, a coil component can be obtained that has an amorphous insulation layer containing Si and O on the surface of soft magnetic metal grains constituting a magnetic body, and this makes it possible to improve the dielectric strength voltage.

[Circuit Board]

The circuit board pertaining to the fourth aspect of the present invention (hereinafter also referred to simply as “fourth aspect”) is a circuit board carrying the coil component pertaining to the first aspect.

The structure, etc., of the circuit board are not limited in any way, and whatever fits the purpose may be adopted.

The fourth aspect allows for application of high voltage by using the coil component pertaining to the first aspect.

### EXAMPLES

The present invention is explained more specifically using examples below; however, the present invention is not limited to these examples.

### Example 1

<Production of Coil Component and Test Magnetic Bodies>

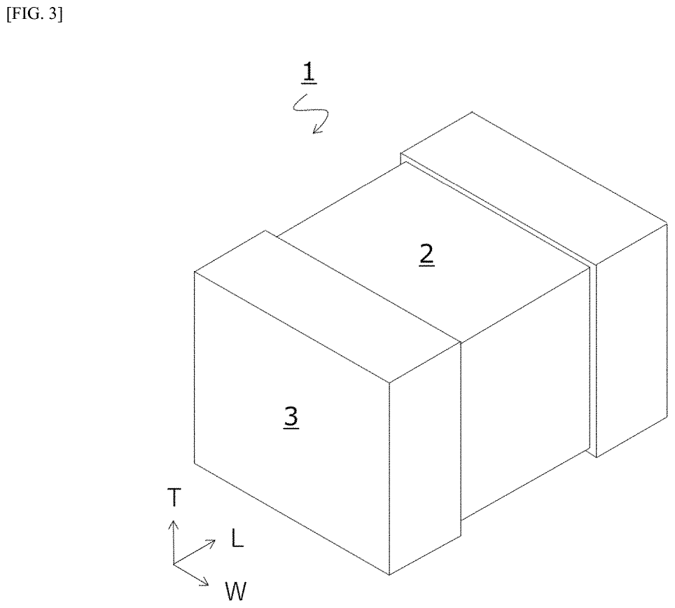

First, a soft magnetic metal powder of 4 μm in average grain size, which contains Fe by 94.5 percent by weight, Si by 2.0 percent by weight, Cr by 3.5 percent by weight, and unavoidable impurities as the remainder, was prepared. Next, this soft magnetic metal powder was mixed with a glass powder whose primary components are Si and B (Si content 70% by mass), a binder resin based on polyvinyl butyral (PVB), and a dispersion medium, to prepare a slurry, and the slurry was formed into a sheet shape using an automatic coating machine to obtain green sheets. Next, an Ag paste was printed on the green sheets to form a precursor to internal conductor. Next, the green sheets were stacked and pressure-bonded and then cut to an individual size, to obtain a compact. Next, the compact was heat-treated for 1 hour at 800° C. in an atmosphere of 800 ppm in oxygen concentration, to obtain a magnetic body with an internal conductor. Lastly, external electrodes that connect to the internal conductor were formed, to obtain a coil component of the shape shown in FIG. 3.

Also, the green sheets having no precursor to an internal conductor formed on them were stacked and pressure-bonded and then processed into a disk shape, and the resulting compact was heat-treated under the aforementioned conditions to obtain a disk-shaped test magnetic body of 7 mm in diameter and 0.5 to 0.8 mm in thickness.

Furthermore, the green sheets having no precursor to an internal conductor formed on them were stacked and pressure-bonded and then processed into a rectangular solid shape, and the resulting compact was heat-treated under the aforementioned conditions to obtain a rectangular-solid-shaped test magnetic body of 50 mm in length, 5 mm in width, and 4 mm in thickness.

<Checking Structure and Composition of Insulation Layer>

When the obtained coil component was checked as to whether the insulation layer in the magnetic body was amorphous or not according to the aforementioned method, it was found to be amorphous. Also, when the composition of the insulation layer was checked according to the aforementioned method, its Si content was 81% by mass, Cr content was 5% by mass, and Fe content was 14% by mass, revealing that it contained more Si than glass phase.

<Measurement of Magnetic Permeability>

The obtained coil component was measured for specific magnetic permeability at a frequency of 10 MHz using an LCR meter (4285A, manufactured by Agilent Technologies, Inc.) as a measurement device. The obtained specific magnetic permeability was 35.

<Evaluation of Electrical Insulating Property>

The coil component was evaluated for electrical insulating property based on the volume resistivity and dielectric breakdown voltage of the aforementioned disk-shaped test magnetic body.

An Au film was formed by sputtering over the entire surface on both sides of the aforementioned disk-shaped test magnetic body, for use as an evaluation sample.

The obtained evaluation sample was measured for volume resistivity according to JIS-K6911. Using the Au films formed on both sides of the sample as electrodes, voltage was applied between the electrodes to an electric field strength of 60 V/cm to measure the resistance value, and the volume resistivity was calculated from this resistance value. The volume resistivity of the evaluation sample was 5.0 kΩ·cm.

Also, the obtained evaluation sample was measured for dielectric breakdown voltage by using the Au films formed on both sides of the sample as electrodes, and applying voltage between the electrodes to measure the current value. The applied voltage was gradually increased to measure the current value, and when the current density calculated from this current value became 0.01 A/cm², the electric field strength calculated from this voltage was taken as the breakdown voltage. The dielectric breakdown voltage of the evaluation sample was 39 kV/cm.

<Evaluation of Mechanical Strength>

The coil component was evaluated for mechanical strength using a 3-point bending test of the aforementioned rectangular-solid-shaped test magnetic body (test piece).

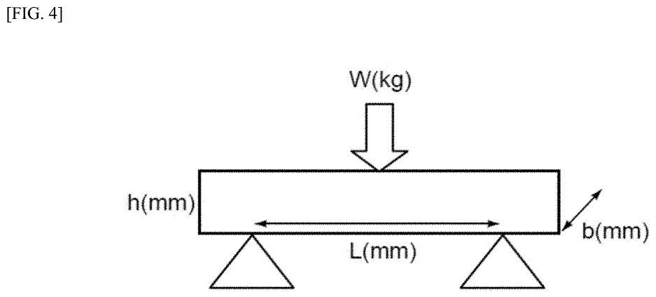

The test piece was supported and a load was applied thereto in the mode shown in FIG. 4, and from the maximum load W causing the test piece to fail, the rupture stress cm was calculated according to (Formula 1) below by considering the bending moment M and the geometrical moment of inertia I. The aforementioned test was conducted on 10 test pieces, and the average value of their rupture stresses σ_{b} was taken as the rupture stress of the magnetic body pertaining to Example 1. The obtained rupture stress was 19 kgf/mm².

$$[ Math . 1 ]$$

$${σ}_{b} = ( \frac{M}{I} ) \times ( \frac{h}{2} ) = \frac{3 WL}{2 {bh}^{2}} \qquad ( Formula 1 )$$

### Example 2

<Production of Coil Component and Test Magnetic Bodies>

The coil component and test magnetic bodies pertaining to Example 2 were produced according to the same method in Example 1, except that a soft magnetic metal powder of 4 μm in average grain size, which contains Fe by 94.5 percent by weight, Si by 3.5 percent by weight, Mn by 2 percent by weight, and unavoidable impurities as the remainder, was used as the material.

<Checking Structure and Composition of Insulation Layer>

When the obtained coil component was checked as to whether the insulation layer in the magnetic body was amorphous or not according to the same method in Example 1, it was found to be amorphous. Also, when the composition of the insulation layer was checked according to the same method in Example 1, its Si content was 80% by mass, revealing that it contained more Si than glass phase.

<Evaluation of Coil Component and Test Magnetic Bodies>

The obtained coil component and test magnetic bodies were measured for properties according to the same methods in Example 1. The coil component had a specific magnetic permeability of 33, and the evaluation sample had a resistivity of 4.8 kΩ·cm, dielectric breakdown voltage of 38 kV/cm, and rupture stress of 18 kgf/mm² based on 3-point bending of the magnetic body.

### Example 3

<Production of Coil Component and Test Magnetic Bodies>

The coil component and test magnetic bodies pertaining to Example 3 were produced according to the same method in Example 1, except in the following respect:

A soft magnetic metal powder from the same lot in Example 1 was dispersed in a mixed solution containing ethanol and ammonia water, and a processing solution containing tetraethoxysilane (TEOS), ethanol, and water was mixed into the dispersion under agitation, after which the soft magnetic metal powder was separated by means of filtration and then dried.

<Checking Structure and Composition of Insulation Layer>

When the obtained coil component was checked as to whether the insulation layer in the magnetic body was amorphous or not according to the same method in Example 1, it was found to be amorphous. Also, when the composition of the insulation layer was checked according to the same method in Example 1, its Si content was 93% by mass, Cr content was 2% by mass, and Fe content was 5% by mass, revealing that it contained more Si than glass phase.

<Evaluation of Coil Component and Test Magnetic Bodies>

The obtained coil component and test magnetic bodies were measured for properties according to the same methods in Example 1. The coil component had a specific magnetic permeability of 21, and the evaluation sample had a resistivity of 5.9 kΩ·cm, dielectric breakdown voltage of 44 kV/cm, and rupture stress of 16 kgf/mm² based on 3-point bending of the magnetic body.

### Example 4

<Production of Coil Component and Test Magnetic Bodies>

The coil component and test magnetic bodies pertaining to Example 4 were produced according to the same method in Example 1, except in the following respect:

A soft magnetic metal powder from the same lot in Example 1 was heat-treated for 1 hour at 700° C. in an atmosphere of 7 ppm in oxygen concentration, prior to mixing with the glass powder.

<Checking Structure and Composition of Insulation Layer>

When the obtained coil component was checked as to whether the insulation layer in the magnetic body was amorphous or not according to the same method in Example 1, it was found to be amorphous. Also, when the composition of the insulation layer was checked according to the same method in Example 1, its Si content was 90% by mass, Cr content was 9% by mass, and Fe content was 1% by mass, revealing that it contained more Si than glass phase.

<Evaluation of Coil Component and Test Magnetic Bodies>

The obtained coil component and test magnetic bodies were measured for properties according to the same methods in Example 1. The coil component had a specific magnetic permeability of 29, and the evaluation sample had a resistivity of 5.8 kΩ·cm, dielectric breakdown voltage of 42 kV/cm, and rupture stress of 16 kgf/mm² based on 3-point bending of the magnetic body.

### Example 5

<Production of Coil Component and Test Magnetic Bodies>

The coil component and test magnetic bodies pertaining to Example 5 were produced according to the same method in Example 4, except that a soft magnetic metal powder from the same lot in Example 2 was used as the material.

<Checking Structure and Composition of Insulation Layer>

When the obtained coil component was checked as to whether the insulation layer in the magnetic body was amorphous or not according to the same method in Example 1, it was found to be amorphous. Also, when the composition of the insulation layer was checked according to the same method in Example 1, its Si content was 88% by mass, revealing that it contained more Si than glass phase.

<Evaluation of Coil Component and Test Magnetic Bodies>

The obtained coil component and test magnetic bodies were measured for properties according to the same methods in Example 1. The coil component had a specific magnetic permeability of 28, and the evaluation sample had a resistivity of 5.6 kΩ·cm, dielectric breakdown voltage of 41 kV/cm, and rupture stress of 17 kgf/mm²based on 3-point bending of the magnetic body.

### Example 6

<Production of Coil Component and Test Magnetic Bodies>

The coil component and test magnetic bodies pertaining to Example 6 were produced according to the same method in Example 4, except that Bi₂O₃—ZnO—B₂O₃-based glass was used as the glass powder.

<Checking Structure and Composition of Insulation Layer>

When the obtained coil component was checked as to whether the insulation layer in the magnetic body was amorphous or not according to the same method in Example 1, it was found to be amorphous. Also, when the composition of the insulation layer was checked according to the same method in Example 1, Si was contained. When the maximum value of Si content in the insulation layer was compared with that in the glass phase, the insulation layer contained more Si than glass phase. Since the glass powder used in this example contained virtually no Si, the Si content can be argued to be higher across the insulation layer than in the glass phase.

<Evaluation of Coil Component and Test Magnetic Bodies>

The obtained coil component and test magnetic bodies were measured for properties according to the same methods in Example 1. The coil component had a specific magnetic permeability of 28, and the evaluation sample had a resistivity of 4.7 kΩ·cm, dielectric breakdown voltage of 36 kV/cm, and rupture stress of 15 kgf/mm² based on 3-point bending of the magnetic body.

### Comparative Example 1

<Production of Coil Component and Test Magnetic Bodies>

The coil component and test magnetic bodies pertaining to Comparative Example 1 were produced according to the same method in Example 1, except in the following respects:

Glass powder was not mixed when the green-sheet-forming slurry was prepared. Also, air was used as the heat treatment atmosphere for the compact.

<Checking Structure and Composition of Insulation Layer>

When the obtained coil component was checked as to whether the insulation layer in the magnetic body was amorphous or not according to the same method in Example 1, it was found to be crystalline. Also, regarding its composition, the Si content was found to be 11% by mass, Cr content 32% by mass, and Fe content 57% by mass.

<Evaluation of Coil Component and Test Magnetic Bodies>

The obtained coil component and test magnetic bodies were measured for properties according to the same methods in Example 1. The coil component had a specific magnetic permeability of 28, and the evaluation sample had a resistivity of 0.10 kΩ·cm, dielectric breakdown voltage of 1 kV/cm, and rupture stress of 7 kgf/mm² based on 3-point bending of the magnetic body.

### Comparative Example 2

<Production of Coil Component and Test Magnetic Bodies>

The coil component and test magnetic bodies pertaining to Comparative Example 2 were produced according to the same method in Example 3, except in the following respects:

Glass powder was not mixed when the green-sheet-forming slurry was prepared. Also, air was used as the heat treatment atmosphere for the compact.

<Checking Structure and Composition of Insulation Layer>

When the obtained coil component was checked as to whether the insulation layer in the magnetic body was amorphous or not according to the same method in Example 1, it was found to be crystalline. Also, regarding its composition, the Si content was found to be 35% by mass, Cr content 28% by mass, and Fe content 37% by mass.

<Evaluation of Coil Component and Test Magnetic Bodies>

The obtained coil component and test magnetic bodies were measured for properties according to the same methods in Example 1. The coil component had a specific magnetic permeability of 24, and the evaluation sample had a resistivity of 0.50 kΩ·cm, dielectric breakdown voltage of 9 kV/cm, and rupture stress of 13 kgf/mm² based on 3-point bending of the magnetic body.

### Comparative Example 3

<Production of Coil Component and Test Magnetic Bodies>

The coil component and test magnetic bodies pertaining to Comparative Example 3 were produced according to the same method in Example 4, except in the following respects:

Glass powder was not mixed when the green-sheet-forming slurry was prepared. Also, air was used as the heat treatment atmosphere for the compact.

<Checking of Structure and Composition of Insulation Layer>

When the obtained coil component was checked as to whether the insulation layer in the magnetic body was amorphous or not according to the same method in Example 1, it was found to be crystalline. Also, regarding its composition, the Si content was found to be 41% by mass, Cr content 35% by mass, and Fe content 24% by mass.

<Evaluation of Coil Component and Test Magnetic Bodies>

The obtained coil component and test magnetic bodies were measured for properties according to the same methods in Example 1. The coil component had a specific magnetic permeability of 33, and the evaluation sample had a resistivity of 2.3 kΩ·cm, dielectric breakdown voltage of 18 kV/cm, and rupture stress of 14 kgf/mm² based on 3-point bending of the magnetic body.

A summary of the above results is shown in Table 1.

TABLE 1

| | | | Dielectric | |
|---|---|---|---|---|
| | | | breakdown | 3-point |
| | μ | Resistivity | voltage | bending test |
| | (at 10 MHz) | [kΩ · cm] | [kV/cm] | [kgf/mm²] |
| Example 1 | 35 | 5.0 | 39 | 19 |
| Example 2 | 33 | 4.8 | 38 | 18 |
| Example 3 | 21 | 5.9 | 44 | 16 |
| Example 4 | 29 | 5.8 | 42 | 16 |
| Example 5 | 28 | 5.6 | 41 | 17 |
| Example 6 | 28 | 4.7 | 36 | 15 |
| Comparative | 28 | 0.1 | 1 | 7 |
| Example 1 | | | | |
| Comparative | 24 | 0.5 | 9 | 13 |
| Example 2 | | | | |
| Comparative | 33 | 2.3 | 18 | 14 |
| Example 3 | | | | |

Based on comparison between the Examples and the Comparative Examples, it can be argued that a coil component constituted by soft magnetic metal grains joined together via a glass phase, wherein the soft magnetic metal grains contain Fe in their metal part and also have, on their surface, an amorphous insulation layer containing Si and O, and wherein the percentage by mass of Si relative to all elements in the insulation layer is higher than that in the glass phase, demonstrates a higher dielectric breakdown voltage compared to a coil component comprising a magnetic body that does not have this constitution. Additionally, it can be argued that the aforementioned constitution also raises the volume resistivity of the magnetic body, and therefore a coil component offering excellent electrical insulating property in general can be obtained. Furthermore, according to the aforementioned constitution, a coil component of high mechanical strength can be obtained.

In all of Comparative Examples 1 to 3, a crystalline insulating film had been formed on the surface of the soft magnetic metal grains. Since the Fe content in the insulating film was higher in these examples than in the Examples, it can be argued that the diffusion of Fe from the metal part into the insulating film contributes to the crystallization of the insulating film.

### INDUSTRIAL APPLICABILITY

According to the present invention, a coil component offering improved dielectric breakdown voltage is provided. The coil component pertaining to the present invention can be used under higher voltages, which makes it suitable for automotive and other applications. Also, according to a preferred mode of the present invention, a coil component of high mechanical strength is provided that can be used in applications where stress is received due to vibration, etc. In these respects, the present invention provides utility.

We/I claim:

1. A coil component comprising: a magnetic body containing soft magnetic metal grains; and a conductor placed inside or on a surface of the magnetic body;
the coil component characterized in that:
in the magnetic body, the soft magnetic metal grains are joined together via a glass phase;
each soft magnetic metal grain contains Fe in its metal part under its surface and has, on the surface, an amorphous insulation layer, other than the glass phase, containing Si and O and covering the metal part; and
a percentage by mass of Si relative to all elements in the insulation layer is higher than a percentage by mass of Si relative to all elements in the glass phase.

2. The coil component according to claim 1, wherein a ratio by mass of Fe in the soft magnetic metal grains is 30% to 98%.

3. The coil component according to claim 1, wherein the soft magnetic metal grains further contain Si in their metal part, and the metal part and the insulating part contain, in common, a non-Si element that oxidizes more easily than Fe.

4. The coil component according to claim 1, wherein the glass phase contains Si.

5. A method for manufacturing a coil component comprising: a magnetic body containing soft magnetic metal grains; and a conductor placed inside or on a surface of the magnetic body;
wherein the method for manufacturing a coil component comprises:
(a1) preparing a soft magnetic metal powder containing Fe;
(b1) depositing an Si-containing substance onto a surface of each grain constituting the soft magnetic metal powder;
(d1) mixing the soft magnetic metal powder obtained in (b1) above, with a glass powder, to obtain a mixed powder;
(e1) forming the mixed powder obtained in (d1) above, to obtain a compact;
(f1) heat-treating the compact obtained in (e1) above, in an atmosphere of 800 ppm or lower in oxygen concentration at a temperature of 500 to 1000° C., to obtain a magnetic body; and
(g1) performing at least one of (1) and (2) below:
(1) placing a conductor or precursor thereto inside or on a surface of the compact in (e1) above; and
(2) placing a conductor on a surface of the magnetic body after performing (f1) above.

6. The method for manufacturing a coil component according to claim 5, wherein it further comprises, prior to (d1) above:
(c1) heat-treating the soft magnetic metal powder obtained in (b1) above in an inert gas atmosphere at a temperature of 100 to 700° C., or in an atmosphere of 100 ppm or lower in oxygen concentration at a temperature of 100 to 300° C.

7. The method for manufacturing a coil component according to claim 5,
wherein the method comprises, in place of (a1) above:
(a2) preparing a soft magnetic metal powder containing Fe, Si, and a non-Si element that oxidizes more easily than Fe; and
wherein the method further comprises, prior to (d1) above:
(c2) heat-treating the soft magnetic metal powder in an atmosphere of 3 to 100 ppm in oxygen concentration at a temperature of 300 to 900° C.

8. A method for manufacturing a coil component comprising: a magnetic body containing soft magnetic metal grains; and a conductor placed inside or on a surface of the magnetic body;
wherein the method for manufacturing a coil component comprises:
(a2) preparing a soft magnetic metal powder containing Fe, Si, and a non-Si element that oxidizes more easily than Fe;
(d2) mixing the soft magnetic metal powder with a glass powder, to obtain a mixed powder;
(e2) forming the mixed powder obtained in (d2) above, to obtain a compact;
(f2) heat-treating the compact obtained in (e2) above, in an atmosphere of 10 to 800 ppm in oxygen concentration at a temperature of 500 to 900° C., to obtain a magnetic body; and
(g2) performing at least one of (1) and (2) below:
(1) placing a conductor or precursor thereto inside or on a surface of the compact in (e2) above; and
(2) placing a conductor on a surface of the magnetic body after performing (f2) above.

9. The method for manufacturing a coil component according to claim 8,
wherein the method further comprises, prior to (d1) above:
(c3) heat-treating the soft magnetic metal powder in an atmosphere of 3 to 100 ppm in oxygen concentration at a temperature of 300 to 900° C.; and
wherein it includes, in place of (f2) above:
(f3) heat-treating the compact obtained in (e2) above, in an atmosphere of 800 ppm or lower in oxygen concentration at a temperature of 500 to 1000° C., to obtain a magnetic body.

10. The method for manufacturing a coil component according to claim 5, wherein, as the glass powder, a glass powder with a softening point of 1000° C. or lower is used.

11. The method for manufacturing a coil component according to claim 8, wherein, as the glass powder, a glass powder with a softening point of 1000° C. or lower is used.

12. A circuit board carrying the coil component according to claim 1.
